(19) United States
(12) Patent Application Publication
(10) Pub. No.: US 2024/0071868 A1
(43) Pub. Date: Feb. 29, 2024

(54) SEMICONDUCTOR DEVICE

(71) Applicant: Mitsubishi Electric Corporation, Tokyo (JP)

(72) Inventor: Kenta NAKAHARA, Tokyo (JP)

(73) Assignee: Mitsubishi Electric Corporation, Tokyo (JP)

(21) Appl. No.: 18/260,592

(22) PCT Filed: Mar. 29, 2021
(86) PCT No.: PCT/JP2021/013259

§ 371 Date: Jul. 6, 2023

(51) Int. Cl. H01L 23/48

(52) U.S. Cl. CPC H01L 23/48

(57) ABSTRACT

A semiconductor device includes a circuit substrate having a circuit pattern and a terminal. The terminal includes an electrode bonding portion, a main wiring portion, and a pair of sub wiring portions. The lower surface of the electrode bonding portion is bonded to the circuit pattern with a bonding material. The main wiring portion is provided upright with a side of the electrode bonding portion. The pair of sub wiring portions extending from the both ends of the main wiring portion in the width direction along sides adjacent to a side of the electrode bonding portion. The lower end portions of the pair of sub wiring portions protrude below the lower surface of the electrode bonding portion. The lower end portions of the pair of sub wiring portions are bonded to the circuit pattern together with the lower surface of the electrode bonding portion by the bonding material.

### TECHNICAL FIELD

The present disclosure relates to a semiconductor device.

### BACKGROUND ART

Conventionally, a semiconductor device is provided with a terminal which is an external electrode in which one end portion is bonded to a circuit pattern and an other end portion is connected to an external device. In such a semiconductor device, there has been a problem that, when the bonding area between the circuit pattern and the terminal is small, the current density of the current flowing through the bonding portion between the circuit pattern and the terminal increases, which induces heat at the bonding portion locally when a large current is applied, as a result, the life of the semiconductor device is shortened.

For example, in Patent Document 1, a structure is disclosed in which, in order to increase the bonding area between the electrode and the wiring pattern (corresponding to a circuit pattern), pair of triangular bent portions are provided at the one end portion of the electrode, and the pair of bent portions are bent so as to stand on a bonding surface.

### PRIOR ART DOCUMENTS

### Patent Document(s)

[Patent Document 1] Japanese Utility Model Application Laid-Open No. 02-077870

### SUMMARY

### Problem to be Solved by the Invention

In the technique described in Patent Document 1, the lower ends of the pair of bent portions are bonded to and abut on the wiring pattern; therefore, the bonding surface increases by the area of the lower ends of the pair of bent portions. However, since the area of the lower ends of the pair of bent portions is small, the increase in the bonding surface is small, which does not have enough of an effect in suppressing heat generated at the bonding portion between the wiring pattern and the electrode is obtained.

Accordingly, an object of the present disclosure is to provide a semiconductor device in which heat generated at a bonding portion between a circuit pattern and a terminal when a large current is applied is suppressed.

### Means to Solve the Problem

A semiconductor device according to the present disclosure includes a circuit substrate including a circuit pattern on which a semiconductor element is mounted on the upper surface thereof, and the terminal which is an external electrode in which one end portion is bonded to the circuit pattern and an other end portion is connected to an external device, in which the terminal includes an electrode bonding portion having a rectangular shape in top view, a lower surface thereof is bonded to the circuit pattern by a bonding material, a main wiring portion provided upright with a first side of the electrode bonding portion, and the pair of sub wiring portions extending from both ends of the main wiring portion in a width direction along a second side and a third side adjacent to the first side of the electrode bonding portion, lower end portions of the pair of sub wiring portions protrude below a lower surface of the electrode bonding portion, and the lower end portions of the pair of sub wiring portions are bonded to the circuit pattern together with the lower surface of the electrode bonding portion by the bonding material.

### Effects of the Invention

Accordingly to the present disclosure, the bonding area between the circuit pattern and the terminal increases more than in the case where the lower ends of the pair of sub wiring portions is bonded to the circuit pattern by the bonding material because the lower end portions of the pair of sub wiring portions are bonded to the circuit pattern by the bonding material with the lower end portions thereof protruding below the lower surface of the electrode bonding portion in addition to bonding the circuit pattern and the electrode bonding portion by the bonding material. Accordingly, heat generated at the bonding portion between the circuit pattern and the terminal can be suppressed when a large current is applied.

The objects, features, aspects, and advantages of the present disclosure will become more apparent from the following detailed description and the accompanying drawings.

### BRIEF DESCRIPTION OF DRAWINGS

FIG. 1 A front view illustrating a state in which a terminal included in a semiconductor device according to Embodiment 1 is bonded to a circuit pattern.

FIG. 2 A cross-sectional view taken along the line A-A of FIG. 1.

FIG. 3 A front view of a terminal included in a semiconductor device according to Embodiment 2.

FIG. 4 A cross-sectional view taken along the line B-B of FIG. 3,

FIG. 5 A front view illustrating a state in which the terminal included in the semiconductor device according to Embodiment 2 is bonded to a circuit pattern.

FIG. 6 A cross-sectional view taken along the line C-C of FIG. 5.

FIG. 7 A front view illustrating a state in which a terminal included in a semiconductor device according to Embodiment 3 is bonded to a circuit pattern.

FIG. 8 A cross-sectional view taken along the line D-D of FIG. 7.

FIG. 9 A front view illustrating a state in which a terminal included in a semiconductor device according to Embodiment 4 is bonded to a circuit pattern.

### DESCRIPTION OF EMBODIMENT(S)

### Embodiment 1

<Configuration of Semiconductor Device>

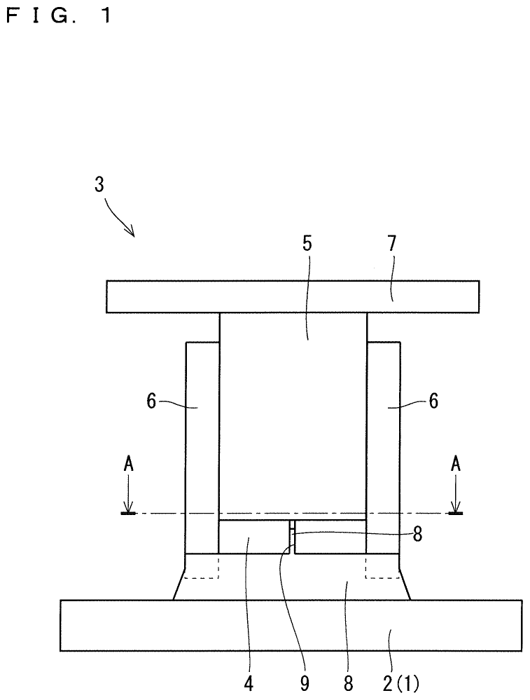

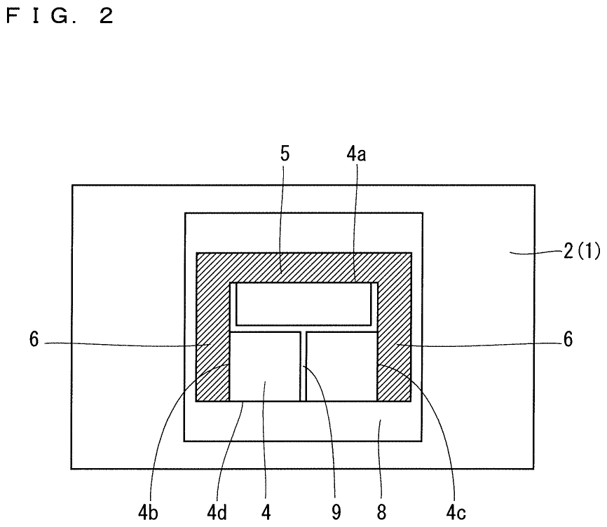

Embodiment 1 will be described below with reference to the drawings. FIG. 1 is a front view illustrating a state in which a terminal 3 included in a semiconductor device according to Embodiment 1 is bonded to a circuit pattern 2. FIG. 2 is a cross-sectional view taken along the line A-A of FIG. 1.

As illustrated in FIGS. 1 and 2, the semiconductor device includes a circuit substrate 1, a semiconductor element (not illustrated), and the terminal 3. Although the semiconductor device further includes a sealing resin (not illustrated) that seals the circuit substrate 1 and the semiconductor element, and a case (not illustrated) that is filled with the sealing resin, those are the conventional components; therefore, the description thereof will be omitted.

The circuit substrate 1 is formed of, for example, ceramic with excellent thermal conductivity such as aluminum nitride or silicon nitride, or resin with excellent thermal conductivity. The circuit pattern 2 is provided on the upper surface of the circuit substrate 1. The circuit pattern 2 is formed of copper, an aluminum alloy, or the like, and the semiconductor element (not illustrated) is mounted on the upper surface of the circuit pattern 2.

The terminal 3, which is an external electrode, has one end portion bonded to the circuit pattern 2 and an other end portion connected to an external device (not illustrated). Specifically, the terminal 3 includes an electrode bonding portion 4, a main wiring portion 5, a pair of sub wiring portions 6, and a device connection portion 7.

The electrode bonding portion 4, the main wiring portion 5, the pair of sub wiring portions 6, and the device connection portion 7 are produced by processing, for example, a single metal plate (hereinafter referred to as “metal plate before processing”) formed of copper or a copper alloy with a certain thickness.

As illustrated in FIG. 2, the electrode bonding portion 4 has sides 4a and 4d facing each other and sides 4b and 4c adjacent to the sides 4a and 4d, and is formed in a rectangular shape in top view. The lower surface of the electrode bonding portion 4 is bonded to the circuit pattern 2 by a bonding material 8 such as solder.

As illustrated in FIGS. 1 and 2, the main wiring portion 5 is provided upright with the side 4a of the electrode bonding portion 4 as the first side. Specifically, the main wiring portion 5 is formed by bending a portion to be the main wiring portion 5 upright with respect to a portion to be the electrode bonding portion 4 of the metal plate before processing along the side 4a. Although not illustrated, the lower end of the main wiring portion 5 is positioned at the same height position as the lower surface of the electrode bonding portion 4 and is bonded to the circuit pattern 2 together with the lower surface of the electrode bonding portion 4 by the bonding material 8.

As illustrated in FIGS. 1 and 2, the pair of sub wiring portions 6 extend from the both ends of the main wiring portion 5 in the width direction along the side 4b as a second side and the side 4c as a third side adjacent to the side 4a of the electrode, bonding portion 4. Specifically, the pair of sub wiring portions 6 are formed by bending portions to be the pair of sub wiring portions 6 with respect to the portion to be the main wiring portion 5 of the metal plate before processing to the directions to the sides 4b and 4c, and are arranged upright along the peripheries of the sides 4b and 4c of the electrode bonding portion 4. The upper ends of the pair of sub wiring portions 6 are positioned above the upper end of the main wiring portion 5.

Meanwhile, the lower end portions of the pair of sub wiring portions 6 protrude below the lower surface of the electrode bonding portion 4. Therefore, the lower end portions of the pair of sub wiring portions 6 are bonded to the circuit pattern 2, by the bonding material 8, together with the lower surface of the electrode bonding portion 4 and the lower end of the main wiring portion 5, with the lower end portions thereof protruding below the lower surface of the electrode bonding portion 4.

The device connection portion 7 is formed by bending the portion to be the device connection portion 7 toward the side 4d opposite to the side 4a of the electrode bonding portion 4 with respect to the portion to be the main wiring portion 5 of the metal plate before processing. and is connected to the external device (not illustrated). The device connection portion 7 is formed in a rectangular shape in top view, and extends from the upper end portion of the main wiring portion 5 toward the side 4d of the electrode bonding portion 4.

Here, the electrode bonding portion 4, the main wiring portion 5, and the pair of sub wiring portions 6 correspond to the one end portion of the terminal 3 bonded to the circuit pattern 2, and the device connection portion 7 corresponds to the other end portion of the terminal 3 to be connected to the external device (not illustrated).

Further, the electrode bonding portion 4 is provided with a groove 9 extending therethrough from the upper surface to the lower surface. As illustrated in FIG. 2, the groove 9 is formed from the central portion of the side 4d along the direction parallel to the sides 4b and 4c of the electrode bonding portion 4 to the central portions of the sides 4b and 4c. Further, the groove 9 is formed such that it is branched at this point in a direction parallel to the sides 4a and 4d and extends to the central portions of the sides 4b and 4c. Furthermore, the groove 9 is formed from these points to the side 4a along the sides 4b and 4c. Further, the width of the upper surface side and the width of the lower surface side of the groove 9 are constant.

When bonding the terminal 3 to the circuit pattern 2, the bonding material 8 is arranged on the upper surface of the circuit pattern 2, and then, heating is performed to a temperature exceeding the melting point of the bonding material 8 in the bonding process, thereby bonding the terminal 3 to the circuit pattern 2. The bonding material 8 melted by heating enters the groove 9 and spreads within the groove 9, so that the bonding strength between the electrode bonding portion 4 and the circuit pattern 2 improves.

<Effect>

As described above, in Embodiment 1, the semiconductor device includes the circuit substrate 1 including the circuit pattern 2 on which the semiconductor element is mounted on the upper surface thereof, and the terminal 3 which is the external electrode in which the one end portion is bonded to the circuit pattern 2 and the other end portion is connected to the external device, in which the terminal 3 includes the electrode bonding portion 4 having a rectangular shape in top view, the lower surface of which is bonded to the circuit pattern 2 by the bonding material 8, the main wiring portion 5 provided upright with the side 4a of the electrode bonding portion 4, and the pair of sub wiring portions 6 extending from the both ends of the main wiring portion 5 in the width direction along the sides 4b and 4c adjacent to the side 4a of the electrode bonding portion 4, the lower end portions of the pair of sub wiring portions 6 protrude below the lower surface of the electrode bonding portion 4, and the lower end portions of the pair of sub wiring portions 6 are bonded to the circuit pattern 2 together with the lower surface of the electrode bonding portion 4 by the bonding material 8.

Accordingly, the bonding area between the circuit pattern 2 and the terminal 3 increases more than in the case where the lower ends of the pair of sub wiring portions 6 is bonded to the circuit pattern 2 by the bonding material 8 because the lower end portions of the pair of sub wiring portions 6 are bonded to the circuit pattern 2 by the bonding material 8 with the lower end portions thereof protruding below the lower surface of the electrode bonding portion 4 in addition to bonding the circuit pattern 2 and the electrode bonding portion 4 by the bonding material 8. As a result, heat generated at the bonding portion between the circuit pattern 2 and the terminal 3 can be suppressed when a large current is applied. Therefore, the longer use of the semiconductor device is made possible.

In addition, the groove 9 extending therethrough from the upper surface to the lower surface is formed in the electrode bonding portion 4; therefore, as the bonding material 8 melted by heating spreads in the groove 9, improving the bonding strength between the electrode bonding portion 4 and the circuit pattern 2. This improves the reliability of the semiconductor device.

### Embodiment 2

<Configuration of Semiconductor Device>

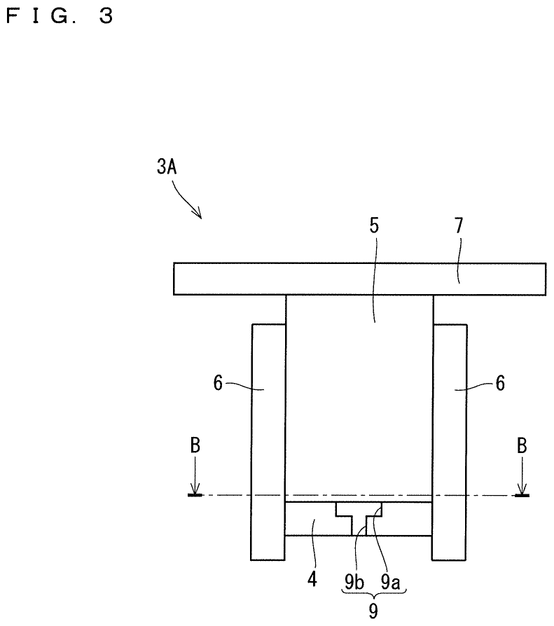

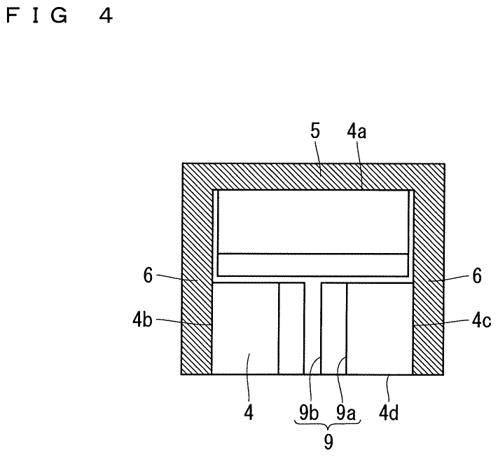

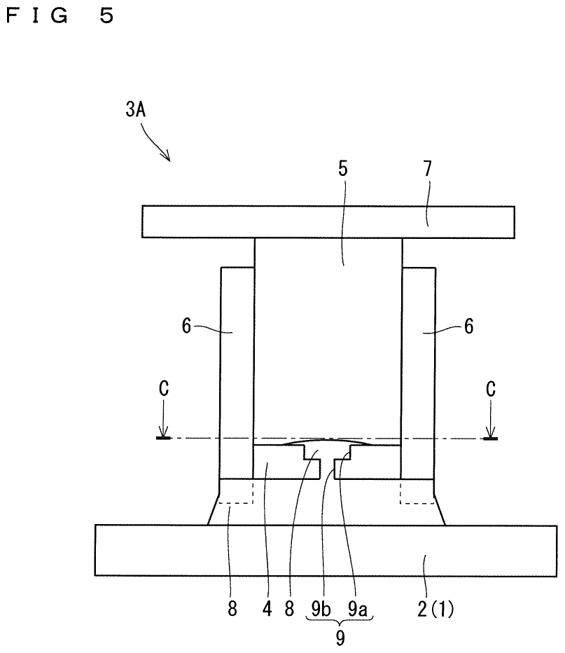

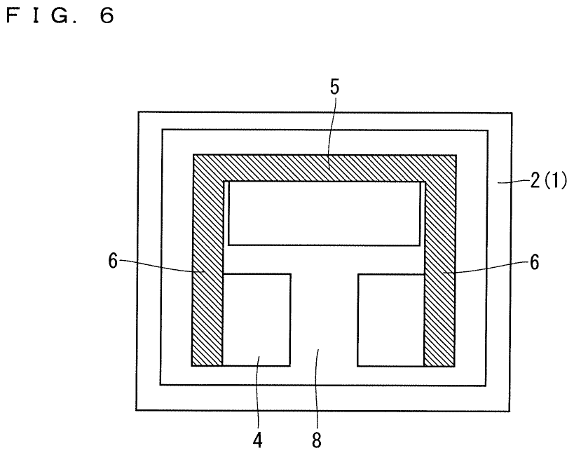

Next, a semiconductor device according to Embodiment 2 will be described. FIG. 3 is a front view illustrating a state in which a terminal 3A included in a semiconductor device according to Embodiment 2. FIG. 4 is a cross-sectional view taken along the line B-B of FIG. 3. FIG. 5 is a front view illustrating a state in which the terminal 3A included in the semiconductor device according to Embodiment 2 is bonded to the circuit pattern 2. FIG. 6 is a cross-sectional view taken along the line C-C of FIG. 5. In Embodiment 2, the same components as those described in Embodiment 1 are denoted by the same reference numerals, and the description thereof is omitted.

As illustrated in FIGS. 3 and 4, in Embodiment 2, the shape of the groove 9 is different from that in Embodiment 1. In Embodiment 1, the width of the upper surface side and the width of the lower surface side of the groove 9 are constant, and in Embodiment 2, the width of the upper surface side is formed wider than the width of the lower surface side in the groove 9.

The groove 9 has a widened portion 9a on the upper surface side and a constant width portion 9b on the lower face side. The widened portion 9a has a constant width on the upper surface side of the groove 9 that is wider than the constant width portion 9b. The constant width portion 9b is formed on the lower surface side of the groove 9 and communicates with the widened portion 9a. The constant width portion 9b has a constant width that is narrower than that of the widened portion 9a. The bonding material 8 melted by heating enters the groove 9 and spreads within the groove 9, so that the bonding strength between the electrode bonding portion 4 and the circuit pattern 2 improves. Providing the recessed widened portion 9a on the upper surface side of the groove 9 creates an anchoring effect on the bonding material 8 filled in the groove 9.

In the groove 9, in terms of a portion formed from the central portion of the side 4d along the direction parallel to the sides 4b and 4c of the electrode bonding portion 4 to the central portions of the sides 4b and 4c, and a portion formed such that it is branched at this point in a direction parallel to the sides 4a and 4d and extends to the central portions of the sides 4b and 4c, the width of the upper surface side is formed wider than the width of the lower surface side. Meanwhile, the width of the upper surface side and the width of the lower surface side are constant in the portions formed from the central portions of the sides 4b and 4c to the side 4a.

Also, in order to effectively function the anchoring effect, as illustrated in FIGS. 5 and 6, the bonding material 8 filled in the groove 9 desirably spreads to cover the periphery of the groove 9 on the upper surface of the electrode bonding portion 4.

<Effect>

As described above, in the semiconductor device according to Embodiment 2, the width of the upper surface side of the groove 9 being wider than the width of the lower surface side allows to create the anchoring effect on the bonding material 8 filled in the groove 9; therefore, improving the bonding strength between the electrode bonding portion 4 and the circuit pattern 2. This improves the reliability of the semiconductor device.

### Embodiment 3

<Configuration of Semiconductor Device>

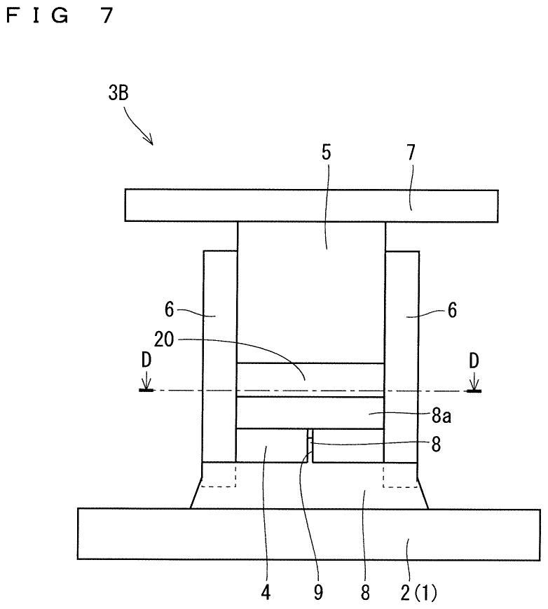

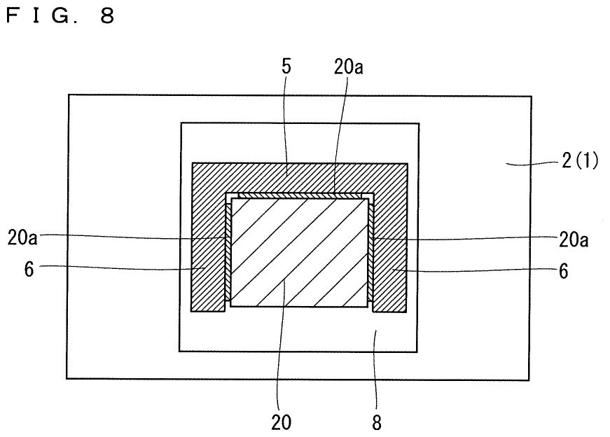

Next, a semiconductor device according to Embodiment 3 will be described. FIG. 7 is a front view illustrating a state in which a terminal 3B included in a semiconductor device according to Embodiment 3 is bonded to a circuit pattern 2. FIG. 8 is a cross-sectional view taken along the line D-D of FIG. 7. It should be noted that, in Embodiment 3, the same components as those described in Embodiments 1 and 2 are denoted by the same reference numerals, and the description thereof is omitted.

As illustrated in FIGS. 7 and 8, Embodiment 3 differs from Embodiment 1 in that a metal plate 20 is provided.

The metal plate 20 is formed of copper, an aluminum alloy, or the like, and is formed to have the same thickness as the electrode bonding portion 4, and is smaller in contour than that of the electrode bonding portion 4 in top view. In addition, the metal plate 20 is arranged above the electrode bonding portion 4 in a portion surrounded by the main wiring portion 5 and the pair of sub wiring portions 6, and is bonded to the main wiring portion 5 and the pair of sub wiring portions 6 by a bonding material 20a such as solder. Furthermore, the lower surface of the metal plate 20 is bonded to the upper surface of the electrode bonding portion 4 by a bonding material 8a such as solder.

In order to reduce the heat generated at the bonding portion between the circuit pattern 2 and the terminal 3B when a large current is applied, increasing the current path of terminal 3B is effective, as well as increasing the bonding area between the circuit pattern 2 and the terminal 3B. A metal plate 20 is provided above the electrode bonding portion 4 in order to increase the current path of the terminal 3B. Instead of the metal plate 20, a metal block thicker than the thickness of the metal plate 20 may be provided.

<Effect>

As described above, in the semiconductor device according to Embodiment 3, the metal plate 20 or the metal block is provided above the electrode bonding portion 4, and the metal plate 20 or the metal block are connected to the main wiring portion 5 and the pair of sub wiring portions 6.

Therefore, compared to the case where the metal plate 20 or the metal block is not provided, the electrical resistance of the terminal 3B is reduced due to the increase in the current path of the terminal 3B, further suppressing the heat generated at the bonding portion between the circuit pattern 2 and the terminal 3B when a large current is applied.

Moreover, the heat capacity of the terminal 3B increases by providing the metal plate 20, suppressing the temperature rise of the terminal 3B.

Moreover, employment of the metal plate 20 or the metal block is adoptable to the terminal 3A of Embodiment 2. In the case again, the same effect as that of Embodiment 3 can be obtained.

### Embodiment 4

<Configuration of Semiconductor Device>

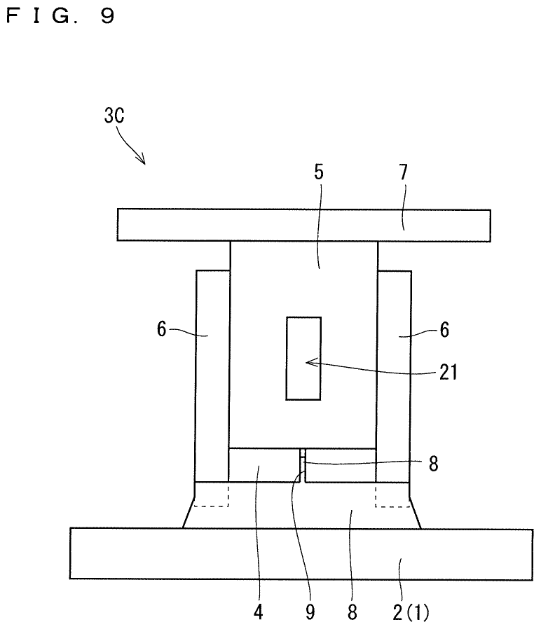

Next, a semiconductor device according to Embodiment 4 will be described. FIG. 9 is a front view illustrating a state in which a terminal 3C included in a semiconductor device according to Embodiment 4 is bonded to a circuit pattern 2. It should be noted that, in Embodiment 4, the description of the same components as those described in Embodiments 1 to 3 will be omitted here.

As illustrated in FIG. 9, Embodiment 4 differs from Embodiment 1 in that a slit 21 is formed that extends through the main wiring portion 5 from the front surface to the back surface.

The slit 21 is formed so as to extend in the vertical direction in the central portion of the main wiring portion 5 in the width direction.

As the current path of the terminal 3C, a path passing through the main wiring portion 5 and a path passing through the pair of sub wiring portions 6 are provided, and more current flows through the path passing through the main wiring portion 5 than through the path passing through the pair of sub wiring portions 6 since the device connection portion 7 is directly connected to the main wiring portion 5. Consequently, heat is likely to be generated in the main wiring portion 5 when a large current is applied. The slit 21 is formed in the main wiring portion 5 in order to reduce the current density of the main wiring portion 5 and make the current density of the main wiring portion 5 and the pair of sub wiring portions 6 equal.

Here, the slit 21 is formed to a size that enables the current density of the main wiring portion 5 and the pair of sub wiring portions 6 to be equalized.

<Effect>

As described above, in the semiconductor device according to Embodiment 4, the slit 21 extending in the vertical direction is formed in the main wiring portion 5; therefore, the current density of the main wiring portion 5 is reduced and the current density of the main wiring portion 5 and the pair of sub wiring portions 6 is made equal. Consequently, heat generated in the main wiring portion 5 can be suppressed when a large current is applied.

Moreover, employment of the slit 21 is adoptable to the terminal 3A of Embodiment 2 and the terminal 3B of Embodiment 3. In the case again, the same effect as that of Embodiment 4 can be obtained.

Although the present disclosure has been described in detail, the foregoing description is, in all aspects, illustrative and not restrictive, and not intended to limit the present disclosure. It is therefore understood that numerous modification examples can be devised.

The Embodiments can be arbitrarily combined, appropriately modified or omitted.

### EXPLANATION OF REFERENCE SIGNS

1 circuit substrate, 2 circuit pattern, 3, 3A, 3B, 3C terminal, 4 electrode bonding portion, 5 main wiring portion, 6 sub wiring portion, 9 groove, 20 metal plate, 21 slit.

1. A semiconductor device comprising:
a circuit substrate including a circuit pattern on which a semiconductor element is mounted on the upper surface thereof; and
the terminal which is an external electrode in which one end portion is bonded to the circuit pattern and an other end portion is connected to an external device, wherein
the terminal includes an electrode bonding portion having a rectangular shape in top view, a lower surface thereof is bonded to the circuit pattern by a bonding material, a main wiring portion provided upright with a first side of the electrode bonding portion, and the pair of sub wiring portions extending from both ends of the main wiring portion in a width direction along a second side and a third side adjacent to the first side of the electrode bonding portion,
lower end portions of the pair of sub wiring portions protrude below a lower surface of the electrode bonding portion, and
the lower end portions of the pair of sub wiring portions are bonded to the circuit pattern together with the lower surface of the electrode bonding portion by the bonding material.

2. The semiconductor device according to claim 1, wherein
the electrode bonding portion is provided with a groove extending therethrough from an upper surface to the lower surface.

3. The semiconductor device according to claim 2, wherein
a width of the groove on an upper surface side is wider than that on the lower surface side.

4. The semiconductor device according to claim 1, wherein
a metal plate or a metal block is provided above the electrode bonding portion, and
the metal plate or the metal block is connected to the main wiring portion and the pair of sub wiring portions.

5. The semiconductor device according to claim 1, wherein
the main wiring portion is provided with a slit extending in the vertical direction.

6. The semiconductor device according to claim 2, wherein
a metal plate or a metal block is provided above the electrode bonding portion, and
the metal plate or the metal block is connected to the main wiring portion and the pair of sub wiring portions.

7. The semiconductor device according to claim 3, wherein
a metal plate or a metal block is provided above the electrode bonding portion, and
the metal plate or the metal block is connected to the main wiring portion and the pair of sub wiring portions.

8. The semiconductor device according to claim 2, wherein
the main wiring portion is provided with a slit extending in the vertical direction.

9. The semiconductor device according to claim 3, wherein
the main wiring portion is provided with a slit extending in the vertical direction.

10. The semiconductor device according to claim 4, wherein
the main wiring portion is provided with a slit extending in the vertical direction.

11. The semiconductor device according to claim 6, wherein
the main wiring portion is provided with a slit extending in the vertical direction.

12. The semiconductor device according to claim 7, wherein
the main wiring portion is provided with a slit extending in the vertical direction.
